(19) United States
(12) Patent Application Publication
(10) Pub. No.: US 2013/0299920 A1
(43) Pub. Date: Nov. 14, 2013

(54) SEMICONDUCTOR DEVICE AND METHOD FOR MANUFACTURING THE SAME

(71) Applicants: Haizhou Yin, Poughkeepsie, NY (US); Keke Zhang, Beijing (CN)

(72) Inventors: Haizhou Yin, Poughkeepsie, NY (US); Keke Zhang, Beijing (CN)

(21) Appl. No.: 13/698,284

(22) PCT Filed: Jul. 3, 2012
(86) PCT No.: PCT/CN12/00913

§ 371 Date: Nov. 16, 2012

(30) Foreign Application Priority Data
May 8, 2012 (CN) 201210139862.3

(51) Int. Cl. H01L 29/78; H01L 29/66

(52) U.S. Cl. CPC H01L 29/78; H01L 29/66477
USPC 257/408; 438/305

(57) ABSTRACT

The present invention discloses a semiconductor device, comprising a substrate, a gate stack structure on the substrate, a gate spacer structure at both sides of the gate stack structure, source/drain regions in the substrate and at opposite sides of the gate stack structure and the gate spacer structure, characterized in that the gate spacer structure comprises at least one gate spacer void filled with air. In accordance with the semiconductor device and the method for manufacturing the same of the present invention, carbon-based materials are used to form a sacrificial spacer, and at least one air void is formed after removing the sacrificial spacer, the overall dielectric constant of the spacer is effectively reduced. Thus, the gate parasitic capacitance is reduced and the device performance is enhanced.

### CROSS REFERENCE

This application is a National Phase application of, and claims priority to, PCT Application No. PCT/CN2012/000913, filed on Jul. 3, 2012, entitled ‘SEMICONDUCTOR DEVICE AND METHOD FOR MANUFACTURING THE SAME’, which claimed priority to Chinese Application No. CN 201210139862.3, filed on May 8, 2012. Both the PCT Application and Chinese Application are incorporated herein by reference in their entireties.

### FIELD OF THE INVENTION

The present invention relates to a semiconductor device and a method for manufacturing the same, in particular, relates to a semiconductor device that is capable of reducing gate parasitic capacitance effectively and a method for manufacturing the same.

### BACKGROUND OF THE INVENTION

It is generally believed that a MOSFET involves at least two kinds of parasitic capacitances—pn-junction capacitance and overlap capacitance. The former one is the parasitic pn-junction capacitance formed between the source/drain region and the substrate, and the latter one is the parasitic capacitance formed between the gate and the source/drain due to local overlap. Both of the two kinds of capacitances are distributed along a direction perpendicular to the substrate surface, and affect the electrical performance of the device seriously. With a continuous reduction in the device size and an increase in the fine process capability, the overlap capacitance is gradually and effectively reduced due to control of the area of the overlap region. The pn-junction capacitance of the substrate is effectively controlled by using substrate isolation technology such as SOI.

However, parasitic capacitance which is distributed parallel to the substrate surface—gate spacer capacitance still exists between the gate and the source/drain region, particularly the gate and the metal silicide contact on the source/drain region. With a decrease in the thickness of the spacer caused by reduction in device size, the spacer capacitance increases gradually and it even overtakes the previous two capacitances and becomes a very important parameter restricting the device performance. The spacer capacitance depends on the geometric shape of the spacer achieved with technological conditions and the materials for forming the spacer. Traditionally, the gate spacer is made of silicon nitride having a relatively great dielectric constant and thus can provide good insulation isolation, but it also results in a greater spacer capacitance.

Accordingly, it is an urgent need to improve the above gate spacer to thereby decrease the gate parasitic capacitance, so as to improve the device performance effectively.

### SUMMARY OF THE INVENTION

As stated above, the present invention aims to provide a semiconductor device that is capable of reducing the gate parasitic capacitance and improving device performance effectively and a method for manufacturing the same.

Therefore, the present invention provides a semiconductor device, comprising a substrate, a gate stack structure on the substrate, a gate spacer structure at both sides of the gate stack structure, source/drain regions in the substrate and at opposite sides of the gate stack structure and the gate spacer structure, characterized in that the gate spacer structure comprises at least one gate spacer void filled with air.

In one embodiment of the present invention, the gate spacer structure comprises a first gate spacer, a third gate spacer and the at least one gate spacer void filled with air, the first gate spacer and the third gate spacer being made of silicon nitride or silicon oxynitride, and the at least one gate spacer void filled with air being sandwiched between the first gate spacer and the third gate spacer.

In another embodiment of the present invention, the source/drain regions comprise lightly-doped source/drain extension regions and heavily-doped source/drain regions.

In another embodiment of the present invention, the semiconductor device further comprises metal silicides formed on the source/drain regions.

In still another embodiment of the present invention, the gate stack structure comprises a gate insulating layer, a work function regulating metal layer, and a resistance regulating metal layer.

The present invention also provides a method for manufacturing a semiconductor device, comprising the steps of: forming a dummy gate stack structure on a substrate; forming a gate spacer structure in the substrate at both sides of the dummy gate stack structure, forming source/drain regions in the substrate at opposite sides of the dummy gate stack structure, wherein the gate spacer structure comprises a first gate spacer, a second gate spacer, and a third gate spacer; performing etching to remove the dummy gate stack structure to form a gate trench; forming a gate stack structure in the gate trench; and performing etching to remove the second gate spacer of the gate spacer structure, so as to form at least one gate spacer void filled with air in the gate spacer structure.

In one embodiment of the present invention, the second gate spacer comprises a carbon-based material.

In another embodiment of the present invention, the carbon-based material comprises at least one of an amorphous carbon thin film and a hydrogenated amorphous carbon thin film.

In another embodiment of the present invention, the step of forming the gate spacer structure and the source/drain regions further comprises: forming a first gate spacer on the substrate at both sides of the dummy gate stack structure; taking the first gate spacer as a mask to perform a first source/drain ion implantation, so as to form lightly-doped source/drain extension regions in the substrate at opposite sides of the dummy gate stack structure; forming a second gate spacer on the first gate spacer; forming a third gate spacer on the second gate spacer; and taking the third gate spacer as a mask to perform a second source/drain ion implantation, so as to form heavily-doped source/drain regions.

In another embodiment of the present invention, after forming the source/drain regions and before performing etching to remove the dummy gate stack structure, the method further comprises the step of: forming metal silicides on the source/drain regions.

In another embodiment of the present invention, the second gate spacer is removed by oxygen plasma etching.

In another embodiment of the present invention, the step of forming the gate stack structure further comprises: depositing a work function regulating metal layer on the gate insulating layer in the gate trench; and depositing a resistance regulating metal layer on the work function regulating metal layer.

In the semiconductor device and the method for manufacturing the same according to the present invention, a carbon-based material are used to form a sacrificial spacer, at least one air void is formed after performing etching to remove the sacrificial spacer, and the overall dielectric constant of the spacer is effectively reduced. Thus the gate parasitic capacitance is reduced and the device performance is enhanced.

### BRIEF DESCRIPTION OF THE DRAWINGS

The technical solution of the present invention will be described in detail with reference to the drawings below, wherein:

FIGS. 1 to 15 are diagrammatic cross-sections of the steps of the method for manufacturing a semiconductor device in accordance with the present invention.

### DETAILED DESCRIPTION OF THE EMBODIMENTS

The features and the technical effects of the technical solution of the present application will be described in detail in combination with the illustrative embodiments with reference to the drawings, and disclosed herein a semiconductor device that is capable of reducing gate parasitic capacitance effectively and a method for manufacturing the same. It should be pointed out that like reference signs indicate like structures, the terms such as “first”, “second”, “on”, “below” used in the present invention may be used to modify various device structures or manufacturing processes. Except for specific explanations, these modifications do not imply the spatial, sequential or hierarchical relationships of the structures of the modified device or the manufacturing processes.

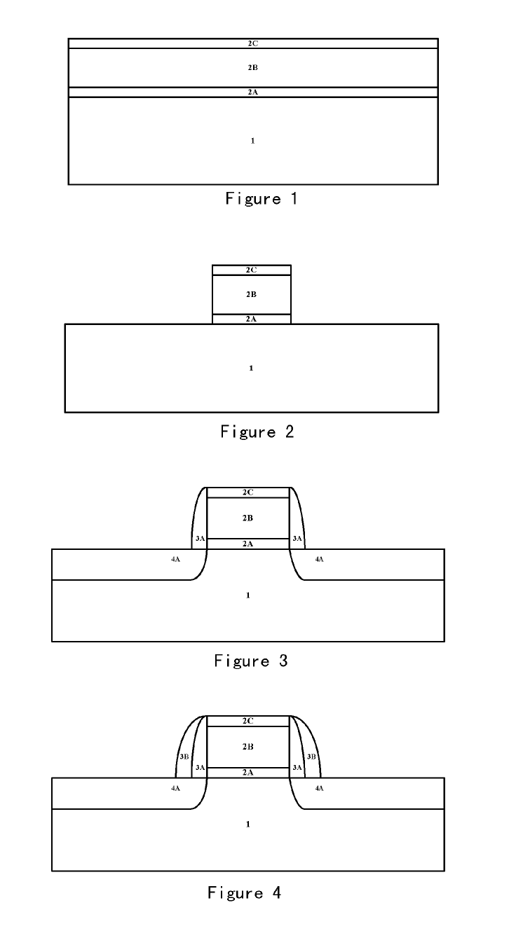

FIGS. 1 to 15 are diagrammatic cross-sections of the steps of the method for manufacturing a semiconductor device in accordance with the present invention.

Referring to FIGS. 1 and 2, a dummy gate stack structure 2 is formed on the substrate 1. There is provided a substrate 1, e.g., made of silicon-based materials, including bulk silicon (Si), silicon on insulator (SOI), SiGe, SiC, strained silicon, silicon nanotube etc. Preferably, bulk silicon or SOI is selected to form the substrate 1, so as to be compatible with the CMOS technology. As shown in FIG. 1, a gate insulating layer 2A, a dummy gate layer 2B, and a dummy gate cap layer 2C are deposited on the substrate 1 sequentially by conventional processes such as LPCVD, PECVD, HDPCVD, ALD, MBE and sputtering. The gate insulating layer 2A may be conventional silicon oxide, namely to function as a pad oxide layer for protecting the channel region of the substrate from being overetched in a gate last process. After removing the dummy gate and the gate insulating layer 2A to form a gate trench, high-K materials are refilled to form a final gate insulating layer. The gate insulating layer 2A may also be made of high-K materials, and will not be removed after its formation; instead it is directly retained as the final gate insulating layer 2A. The high-K materials include but are not limited to nitride (e.g., SiN, AlN, TiN), metal oxide (mainly including oxide of subgroup and lanthanide metal element such as Al₂O₃, Ta₂O₅, TiO₂, ZnO, ZrO₂, HfO₂, CeO₂, Y₂O₃, La₂O₃), perovskite phase oxide (e.g., PbZrₓTi₁₋ₓO₃ (PZT), BaₓSr₁₋ₓTiO₃ (BST)). The dummy gate layer 2B is made of silicon-based materials, including polysilicon, amorphous silicon, and microcrystalline silicon. The dummy gate cap layer 2C is made of materials with relatively high hardness such as silicon nitride, silicon oxynitride, and diamond-like carbon (DLC) for protecting and controlling the shape of the dummy gate layer 2B. However, the dummy gate cap layer 2C may be omitted if the subsequent photolithography/etching can be controlled accurately. Thus, the dummy gate stack structure 2 may substantially include the gate insulating layer (pad oxide layer) 2A and the dummy gate layer 2B only. As shown in FIG. 2, the gate insulating layer 2A, the dummy gate layer 2B, and the dummy gate cap layer 2C are photoetched/etched to form the dummy gate stack structure 2.

Referring to FIGS. 3 to 5, a multi-layer gate spacer 3 is formed on the substrate at both sides of the dummy gate stack structure 2, and source/drain ion implantation is performed to form source/drain regions 4 in the substrate 1 at opposite sides of the gate spacer 3, wherein the multi-layer gate spacer 3 at least comprises a sacrificial spacer 3B made of a carbon-based material.

As shown in FIG. 3, a first gate spacer 3A is formed on the substrate 1 at both sides of the dummy gate stack structure 2 by depositing by means of conventional processes such as LPCVD, PECVD, HDPCVD, ALD, MBE and sputtering and then performing etching, wherein the material of the first gate spacer 3A may be a silicon-based material such as silicon nitride and silicon oxynitride. The dummy gate stack structure 2 and the first dummy gate spacer 3A are taken as a mask to perform a first source/drain ion implantation, so as to form lightly-doped source/drain extension regions 4A and halo source/drain doped regions (not shown) in the substrate 1 at both sides of the first dummy gate spacer 3A. The type, dosage, and energy of dopant ions are determined based on the type of the MOSFET and the junction depth, and no more unnecessary details will be provided here.

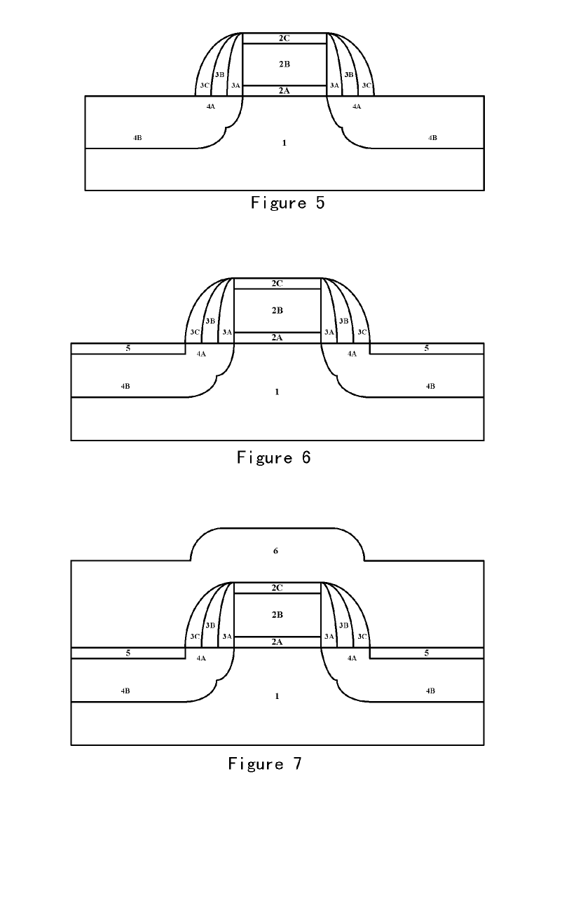

As shown in FIG. 4, a second gate spacer 3B is formed on the first gate spacer 3A by depositing by means of processes such as cathode ray deposition, radio frequency sputtering, ion beam deposition, MVPECVD, RFPECVD, and HDPCVD and then performing etching, wherein the material of the second gate spacer 3B may be a carbon-based material, including at least one of an amorphous carbon thin film (a-C) and a hydrogenated amorphous carbon thin film (a-C:H). Preferably, the amorphous carbon thin film or the hydrogenated amorphous carbon thin film having better conformal effect is obtained by using HDPCVD. The second gate spacer 3B will be removed in the subsequent etching process to form a gate spacer void, to thereby effectively decrease the gate parasitic capacitance by replacing the second gate spacer 3B with air which has a relative dielectric constant of 1, thus the second gate spacer 3B may also be called a sacrificial spacer.

As shown in FIG. 5, a third gate spacer 3C is formed on the second gate spacer 3B by depositing by means of conventional processes such as LPCVD, PECVD, HDPCVD, ALD, MBE and sputtering and then performing etching, wherein the material of the third gate spacer 3C may be a silicon-based material such as silicon nitride and silicon oxynitride. The third gate spacer 3C is taken as a mask to perform a second source/drain ion implantation, so as to form heavily-doped source/drain regions 4B in the substrate 1 at both sides of the third gate spacer 3C. The dopant ions for the second ion implantation is of the same type as those for the first ion implantation, but the dosage and energy for the second ion implantation are larger to thereby form heavily-doped regions.

Preferably, referring to FIG. 6, metal silicides 5 are formed on the source/drain regions 4 by conventional processes such as sputtering and MOCVD. A metal layer (not shown) made of, e.g., nickel-based metal including at least one of Ni, NiPt, NiCo, and NiPtCo with a thickness of about, e.g., 1˜10 nm is deposited on the entire device, then annealing is performed at a temperature of about, e.g., 450˜550□ such that the metal layer reacts with the Si in the source/drain regions 4 to produce metal silicides 5 for reducing the source/drain resistance of the device. The metal silicides 5 may be, e.g., NiSi, NiPtSi, NiCoSi, and NiPtCoSi with a thickness of about, e.g., 1˜30 nm.

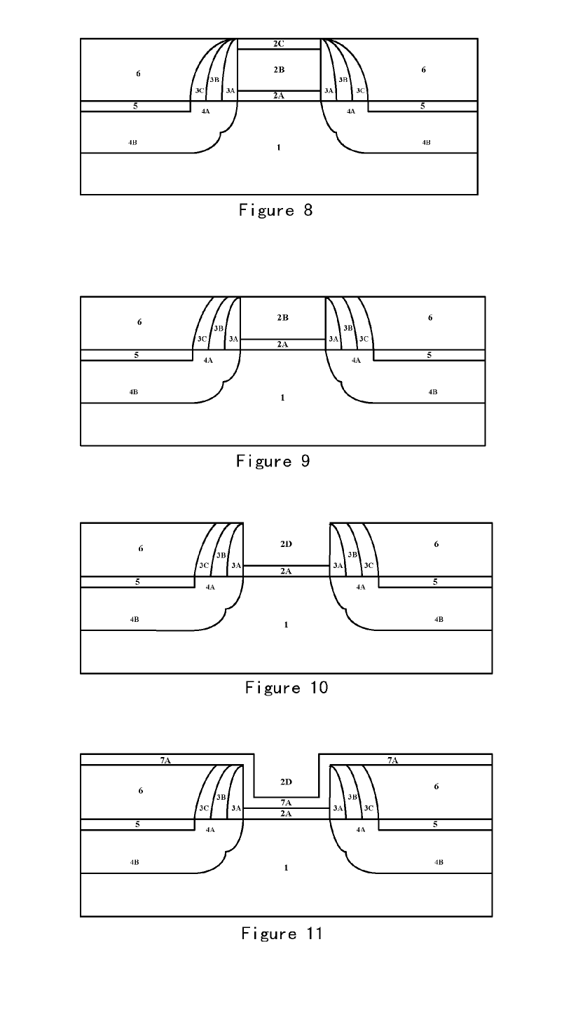

Then, referring to FIGS. 7 to 13, the dummy gate stack structure 2 is removed to form a gate trench, and the gate trench is filled to form a gate stack structure 7.

Referring to FIG. 7, an interlayer dielectric layer (ILD) 6 is deposited on the entire device by conventional processes such as LPCVD, PECVD, HDPCVD, and spin coating. The ILD 6 is made of, e.g., silicon oxide or a low-K material including but not limited to organic low-K materials (e.g., aryl- or polycyclic organic polymer), inorganic low-K materials (e.g., amorphous carbon nitride thin film, polycrystalline boron nitride thin film, fluorosilicate glass), porous low-K materials (e.g., Silsesquioxane (SSQ)-based porous low-K materials, porous silicon dioxide, porous SiOCH, C-doped silicon dioxide, F-doped porous amorphous carbon, porous diamond, porous organic polymer).

Referring to FIGS. 8 and 9, the ILD 6 and the dummy gate cap layer 2C are planarized until the dummy gate layer 2B is exposed. As shown in FIG. 8, the ILD 6 made of a low-K material is planarized by a first CMP until the dummy gate cap layer 2C made of nitride is exposed. Then, as shown in FIG. 9, the CMP grinding fluid, grinding pad and termination conditions are renewed to perform a second CMP, and the dummy gate cap layer 2C is planarized until the dummy gate layer 2B made of a silicon-based material is exposed.

Referring to FIG. 10, the dummy gate layer 2B is removed by etching to form a gate trench 2D. As shown in FIG. 10, dry etching by means of fluorine-based plasma, chlorine-based plasma or bromine-based plasma etc., or wet etching with solutions of KOH or TMAH is used to remove the dummy gate layer 2B made of a silicon material until the pad oxide layer/gate insulating layer 2A is exposed, and the gate trench 2D is finally formed.

Referring to FIG. 11, a work function regulating metal layer 7A made of a material such as TiN and TaN is deposited on the gate insulating layer 2A in the gate trench 2D and on the ILD 6.

Referring to FIG. 12, a resistance regulating metal layer 7B made of a material such as Ti, Ta, W, Al, Cu and Mo is deposited on the work function regulating metal layer 7A.

Referring to FIG. 13, layers 7B and 7A are planarized until the ILD 6 is exposed, the layers 7A and 7B that fill the gate trench 2D form the final gate stack structure 7 of the MOSFET together.

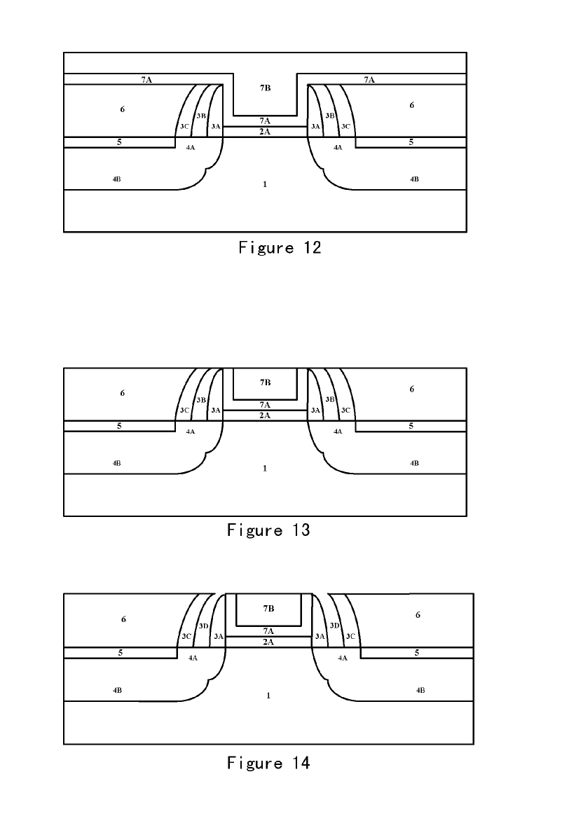

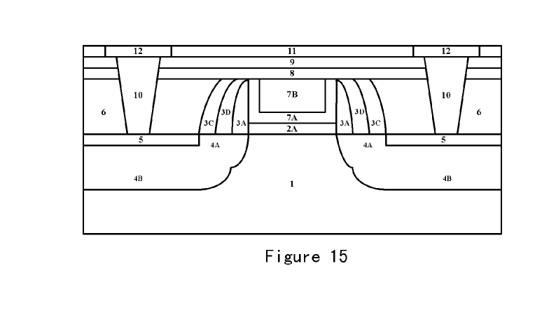

Afterwards, referring to FIG. 14, the second gate spacer 3B is removed by etching to form a gate spacer void 3D. Dry etching such as oxygen plasma etching is used to remove the second gate spacer 3B made of carbon-based materials until the substrate 1 is exposed. The second gate spacer 3B is made of the above carbon-based materials, and it will be removed by etching because in the process of oxygen plasma etching, the amorphous carbon will react with the oxygen to produce carbon dioxide gas and the hydrogenated amorphous carbon will react with the oxygen to produce carbon dioxide and vapor. On the other hand, the substrate 1 made of silicon-based materials will initially react to produce silicon oxide, which covers the surface of the substrate 1 and thereby blocks the further reactive etching Thus, it should be proper to say that the substrate 1 is substantially not reacted and is substantially not etched. The few oxide produced in the process of removing the second gate spacer 3B will have very little influence on the dielectric constant of 3B, and thus it may be not removed or may be removed by wet etching with a HF-based etching solution. Preferably, the HF-based etching solution may be, e.g., diluted HF (DHF) and buffered oxide etch (BOE, mixture of HF and NH₄F). Moreover, strong oxidant such as sulfuric acid and hydrogen peroxide may be added to increase the etching speed. After removing the second gate spacer 3B, a gate spacer void 3D filled with air is formed. The void 3D has a lower relative dielectric constant (with a value of 1), thus can decrease the gate parasitic capacitance effectively. It shall be noted that although the present invention takes an example of forming a void 3D in the embodiment only, it may be appreciated by a person skilled in the art that a laminated structure of more layers, e.g., 3A/3B/3A/3B/3C may be formed, and more than one void 3D may be formed after performing etching.

Thereafter, referring to FIG. 15, subsequent processes are performed. A contact etching stop layer (CESL) 8 made of a material such as SiN and SiON is deposited on the entire device and is joint with the first gate spacer and the third gate spacer 3A/3C which are made of the same material, to thereby seal the gate spacer void 3D. A second ILD 9 is deposited; then the second ILD 9, the CESL 8 and the ILD 6 are etched to form source/drain contact holes; and then metal and/or metal nitride is filled in the source/drain contact holes to form source/drain contact plugs 10. Next, a third ILD 11 is deposited and etched to form electrical contact holes, in which metal is filled to form electrical contacts 12, so as to form the word line or bit line of the device. Thus, the final device structure is completed. As shown in FIG. 15, the final device structure comprises: a substrate 1, a gate stack structure 2A/7A/7B on the substrate 1, a gate spacer structure 3A/3D/3C at both sides of the gate stack structure, source/drain regions 4A/4B in the substrate 1 at opposite sides of the gate spacer structure, wherein the gate spacer structure comprises at least one gate spacer void 3D filled with air.

It shall be noted that although the dummy gate 2B is made of a silicon-based material in the present invention, the same carbon-based material as that of the second gate layer or the sacrificial gate layer 3B may also be used. The dummy gate 2B is removed by oxygen plasma dry etching, and then the channel region of the substrate can be effectively protected without the pad oxide layer 2A. Thus, the process may be further simplified and the device reliability may be further enhanced.

In the semiconductor device and the method for manufacturing the same according to the present invention, a carbon-based material is used to form a sacrificial spacer, and at least one air void is formed after removing the sacrificial spacer. The overall dielectric constant of the spacer is effectively reduced, and thus the gate parasitic capacitance is reduced and the device performance is enhanced.

Although the present invention is described with reference to one or more illustrative embodiments, it may be appreciated by a person skilled in the art that various appropriate variations and equivalent modes may be made to the structure of the device without departing from the scope of the present invention. Furthermore, many modifications that may be applicable to specific situations or materials can be made from the teachings disclosed above without departing from the scope of the present invention. Therefore, the object of the present invention is not to limit the invention to the specific embodiments disclosed as the preferred embodiments for implementing the present invention, the disclosed device structure and the manufacturing method will include all embodiments falling within the scope of the present invention.

1. A semiconductor device, comprising:
a substrate;
a gate stack structure on the substrate;
a gate spacer structure at both sides of the gate stack structure; and source/drain regions in the substrate and at opposite sides of the gate stack structure and the gate spacer structure, wherein the gate spacer structure comprises at least one gate spacer void.

2. The semiconductor device according to claim 1, wherein the gate spacer structure further comprises a first gate spacer, and a third gate spacer, the first gate spacer and the third gate spacer being made of silicon nitride or silicon oxynitride, and at least one gate spacer void filled with air being sandwiched between the first gate spacer and the third gate spacer.

3. The semiconductor device according to claim 1, wherein the source/drain regions comprise lightly-doped source/drain extension regions and heavily-doped source/drain regions.

4. The semiconductor device according to claim 1, wherein the semiconductor device further comprises metal silicides formed on the source/drain regions.

5. The semiconductor device according to claim 1, wherein the gate stack structure comprises a gate insulating layer, a work function regulating metal layer, and a resistance regulating metal layer.

6. A method for manufacturing a semiconductor device, comprising:
forming a dummy gate stack structure on a substrate;
forming a gate spacer structure in the substrate at both sides of the dummy gate stack structure, forming source/drain regions in the substrate at opposite sides of the dummy gate stack structure, wherein the gate spacer structure comprises a first gate spacer, a second gate spacer, and a third gate spacer;
performing etching to remove the dummy gate stack structure to form a gate trench;
forming a gate stack structure in the gate trench; and
performing etching to remove the second gate spacer of the gate spacer structure, so as to form at least one gate spacer void in the gate spacer structure.

7. The method for manufacturing a semiconductor device according to claim 6, wherein the second gate spacer comprises a carbon-based material.

8. The method for manufacturing a semiconductor device according to claim 7, wherein the carbon-based material comprises at least one of an amorphous carbon thin film and a hydrogenated amorphous carbon thin film.

9. The method for manufacturing a semiconductor device according to claim 6, wherein forming the gate spacer structure and the source/drain regions further comprises:
forming a first gate spacer on the substrate at both sides of the dummy gate stack structure;
taking the first gate spacer as a mask to perform a first source/drain ion implantation, so as to form lightly-doped source/drain extension regions in the substrate at opposite sides of the dummy gate stack structure;
forming a second gate spacer on the first gate spacer; and
taking the third gate spacer as a mask to perform a second source/drain ion implantation, so as to form heavily-doped source/drain regions.

10. The method for manufacturing a semiconductor device according to claim 6, wherein after forming the source/drain regions and before performing etching to remove the dummy gate stack structure, the method further comprises forming metal silicides on the source/drain regions.

11. The method for manufacturing a semiconductor device according to claim 6, wherein the second gate spacer is removed by oxygen plasma etching.

12. The method for manufacturing a semiconductor device according to claim 6, wherein forming the gate stack structure further comprises: depositing a work function regulating metal layer on the gate insulating layer in the gate trench; and depositing a resistance regulating metal layer on the work function regulating metal layer.
